(19) United States
(12) Patent Application Publication
(10) Pub. No.: US 2016/0154302 A1
(43) Pub. Date: Jun. 2, 2016

(54) METHOD FOR THE PERPENDICULAR ORIENTATION OF NANODOMAINS OF BLOCK COPOLYMERS, USING STATISTICAL OR GRADIENT COPOLYMERS, THE MONOMERS OF WHICH DIFFER AT LEAST IN PART FROM THOSE PRESENT IN EACH OF THE BLOCKS OF THE BLOCK COPOLYMER

(71) Applicants: ARKEMA FRANCE, Colombes (FR); UNIVERSITE DE BORDEAUX, Bordeaux (FR); CENTRE NATIONAL DE LA RECHERCHE SCIENTIFIQUE, Paris Cedex 14 (FR); INSTITUT POLYTECHNIQUE DE BORDEAUX, Talence Cedex (FR)

(72) Inventors: Christophe NAVARRO, Bayonne (FR); Chrystilla REBOUL, Talence (FR); Guillaume FLEURY, Bordeaux (FR); Gilles PECASTAINGS, Bordeaux (FR); Georges HADZIIOANNOU, Leognan (FR)

(73) Assignees: ARKEMA FRANCE, Colombes (FR); UNIVERSITE DE BORDEAUX, Bordeaux (FR); CENTRE NATIONAL DE LA RECHERCHE SCIENTIFIQUE (CNRS, Paris Cedex 14 (FR); INSTITUT POLYTECHNIQUE DE BORDEAUX, Talence Cedex (FR)

(21) Appl. No.: 14/904,325

(22) PCT Filed: Jul. 10, 2014
(86) PCT No.: PCT/FR2014/051771

§ 371 Date: Jan. 11, 2016

(30) Foreign Application Priority Data
Jul. 11, 2013 (FR) 13.56831

(51) Int. Cl. G03F 7/00; C09D 153/00

(52) U.S. Cl. CPC G03F 7/0002; C09D 153/00

(57) ABSTRACT

The present invention relates to a process for the perpendicular orientation of nanodomains of block copolymers on a substrate by using a sublayer of random or gradient copolymers whose monomers differ at least in part from those present, respectively, in each of the blocks of the block copolymer.

The present invention relates to a process for the perpendicular orientation of nanodomains of block copolymers on a substrate via the use of a sublayer of statistical or gradient copolymers whose monomers differ at least in part from those present, respectively, in each of the blocks of the block copolymer.

This process is advantageously used in lithography.

Many advanced lithography processes based on the self-assembly of block copolymers (BC) involve PS-b-PMMA ((polystyrene-block-poly(methyl methacrylate)) masks. However, PS is a poor mask for etching, since it has a low resistance to the plasmas inherent in the etching step. Consequently, this system does not allow optimum transfer of the patterns to the substrate. Furthermore, the limited phase separation between PS and PMMA due to the low Flory Huggins parameter χ of this system does not make it possible to obtain domain sizes smaller than about twenty nanometers, consequently limiting the final resolution of the mask. To overcome these drawbacks, in “Polylactide-Poly(dimethylsiloxane)-Polylactide Triblock Copolymers as Multifunctional Materials for Nanolithographic Applications”, ACS Nano. 4(2): pages 725-732, Rodwogin, M. D., et al. describe groups containing Si or Fe atoms, such as PDMS, polyhedral oligomeric silsesquioxane (POSS), or alternatively poly(ferrocenylsilane) (PFS) which are introduced into the block copolymers serving as masks. These copolymers may form clearly separated domains similar to those of PS-b-PMMAs, but, unlike them, the oxidation of the inorganic blocks during etching treatments forms an oxide layer which is much more resistant to etching, making it possible to keep intact the pattern of the polymer constituting the lithography mask.

In the article “Orientation-Controlled Self-Assembled Nanolithography Using a Polystyrene-Polydimethylsiloxane Block Copolymer”, Nano Letters, 2007, 7(7): pages 2046-2050, Jung and Ross suggest that the ideal block copolymer mask should have a high χ value, and that one of the blocks should be highly resistant to etching. A high χ value between the blocks promotes the formation of pure domains that are well defined on the entire substrate, as is explained by Bang, J. et al., in “Defect-Free Nanoporous Thin Films from ABC Triblock Copolymers”, J. Am. Chem. Soc., 2006, 128: page 7622, i.e. a decrease in the line roughness. x is equal to 0.04 for the PS/PMMA couple, at 393 K, whereas for PS/PDMS (poly(dimethylsiloxane)), it is 0.191, for PS/P2VP (poly(2-vinylpyridine)), it is 0.178, for PS/PEO (poly(ethylene oxide)), it is 0.077 and for PDMS/PLA (poly(lactic acid)), it is 1.1. This parameter, associated with high contrast during etching between PLA and PDMS, allows a better definition of the domains and thus makes it possible to approach domain sizes of less than 22 nm. All these systems showed good organization with domains having a limit size of less than 10 nm, under certain conditions. However, many systems with a high χ value are organized by means of solvent vapor annealing, since excessively high temperatures would be required for thermal annealing, and the chemical integrity of the blocks would not be conserved.

Among the constituent blocks of the block copolymers that are of interest, mention may be made of PDMS since it has already been used in soft lithography, i.e. lithography not based on interactions with light, more specifically as an ink pad or mold. PDMS has one of the lowest glass transition temperatures Tg of polymer materials. It has high heat stability, low absorption of UV rays and highly flexible chains. Furthermore, the silicon atoms of PDMS give it good resistance to reactive ion etching (RIE), thus making it possible to correctly transfer the pattern formed by the domains onto the substrate layer.

Another block of interest that may be advantageously combined with PDMS is PLA.

Polylactic acid (PLA) is distinguished by its degradability, which allows it to be readily degraded via a chemical or plasma route during the step of creating the copolymer mask (it is twice as sensitive to etching as PS, which means that it can be degraded much more easily). Furthermore, it is easy to synthesize and inexpensive.

It has been demonstrated several times that the use of a PS-s-PMMA random copolymer brush makes it possible to control the surface energy of the substrate, as may be read from the following authors: Mansky, P., et al., “Controlling polymer-surface interactions with random copolymer brushes”, Science, 1997, 275: pages 1458-1460, Han, E., et al., “Effect of Composition of Substrate-Modifying Random Copolymers on the Orientation of Symmetric and Asymmetric Diblock Copolymer Domains”, Macromolecules, 2008, 41(23): pages 9090-9097, Ryu, D. Y., et al., “Cylindrical Microdomain Orientation of PS-b-PMMA on the Balanced Interfacial Interactions: Composition Effect of Block Copolymers. Macromolecules, 2009”, 42(13): pages 4902-4906, In, I., et al., “Side-Chain-Grafted Random Copolymer Brushes as Neutral Surfaces for Controlling the Orientation of Block Copolymer Microdomains in Thin Films”, Langmuir, 2006, 22(18): pages 7855-7860, Han, E., et al., “Perpendicular Orientation of Domains in Cylinder-Forming Block Copolymer Thick Films by Controlled Interfacial Interactions. Macromolecules, 2009”, 42(13): pages 4896-4901; in order to obtain morphologies that are normally unstable, such as cylinders perpendicular to the substrate in a thin film configuration for a PS-b-PMMA block copolymer. The surface energy of the modified substrate is controlled by varying the volume fractions of the random copolymer blocks. This technique is used since it is simple, quick and makes it possible readily to vary the surface energies so as to equilibrate the preferential interactions between blocks and the substrate.

Most of the studies in which a random copolymer brush is used in order to minimize the surface energies show the use of a PS-s-PMMA brush (PS/PMMA random copolymer) for controlling the organization of a PS-b-PMMA. Ji et al. in “Generalization of the Use of Random Copolymers To Control the Wetting Behavior of Block Copolymer Films. Macromolecules, 2008”, 41(23): pages 9098-9103 have demonstrated the use of a PS-s-P2VP random copolymer in order to control the orientation of a PS-b-P2VP, which methodology is similar to that used in the case of the PS/PMMA system.

Few studies mention controlling the orientation of domains by using random or gradient copolymers whose constituent monomers differ at least in part from those present in the block copolymer, and this remains valid for systems other than PS-b-PMMA.

Keen et al. in “Control of the Orientation of Symmetric Poly(styrene)-block-poly(d,l-lactide) Block Copolymers Using Statistical Copolymers of Dissimilar Composition. Langmuir, 2012” have demonstrated the use of a PS-s-PMMA random copolymer for controlling the orientation of a PS-b-PLA. However, it is important to note that, in this case, one of the constituents of the random copolymer is chemically identical to one of the constituents of the block copolymer. Moreover, PS-b-PLA is not the most suitable block copolymer for establishing the smallest nanostructured domains.

Nevertheless, for certain systems such as PDMS/PLA, the synthesis of random copolymers from the respective monomers, making it possible to apply the approach described above, cannot be achieved. Thus, it appears very interesting to circumvent this problem by controlling the surface energies between the substrate and the block copolymer with a material of different chemical nature, but which affords the same final result in terms of functionality.

The applicant has discovered that the use of random or gradient copolymers whose monomers differ at least in part from those present, respectively, in each of the blocks of the deposited block copolymer makes it possible efficiently to solve the problem outlined above and especially to control the orientation of the mesostructure formed by the self-assembly of a block copolymer via a random copolymer not having any chemical relationship with the block copolymer.

### SUMMARY OF THE INVENTION

The invention relates to a process for controlling the orientation of a block copolymer mesostructure by means of a random or gradient copolymer whose constituent monomers differ at least in part from those present, respectively, in each of the blocks of the block copolymer, comprising the following steps:
deposition of a solution of a random or gradient copolymer on a substrate;
annealing bringing about the grafting of a monolayer of chains of the random or gradient copolymer on the substrate, followed by optional rinsing so as to remove the non-grafted chains;
deposition of a solution of the block copolymer;
phase segregation inherent in the self-assembly of the block copolymers via a suitable treatment.

### DETAILED DESCRIPTION

The random or gradient copolymers used in the invention may be of any type, on condition that the constituent monomers thereof differ at least in part from those present, respectively, in each of the blocks of the block copolymer used in the invention.

According to one variant, while being at least partly of different chemical nature, one of the constituent monomers of the random copolymers of the invention is, once polymerized, miscible in one of the blocks of the block copolymers used in the invention.

The random copolymers may be obtained via any route, among which mention may be made of polycondensation, ring-opening polymerization, anionic, cationic or radical polymerization, the latter possibly being controlled or uncontrolled. When the polymers are prepared by radical polymerization or telomerization, said process may be controlled via any known technique such as NMP (“Nitroxide Mediated Polymerization”), RAFT (“Reversible Addition and Fragmentation Transfer”), ATRP (“Atom Transfer Radical Polymerization”), INIFERTER (“Initiator-Transfer-Termination”), RITP (“Reverse Iodine Transfer Polymerization”), ITP (“Iodine Transfer Polymerization”).

Polymerization processes not involving metals will be preferred. Preferably, the polymers are prepared by radical polymerization, and more particularly by controlled radical polymerization, and even more particularly by nitroxide-mediated polymerization.

More particularly, the nitroxides obtained from the alkoxyamines derived from the stable free radical (1) are preferred

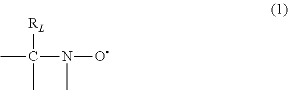

in which the radical R_{L} has a molar mass of greater than 15.0342 g/mol. The radical R_{L} may be a halogen atom such as chlorine, bromine or iodine, a linear, branched or cyclic, saturated or unsaturated hydrocarbon-based group such as an alkyl or phenyl radical, or an ester group —COOR or an alkoxy group —OR, or a phosphonate group —PO(OR)₂, provided that it has a molar mass of greater than 15.0342. The monovalent radical R_{L} is said to be in the β position relative to the nitrogen atom of the nitroxide radical. The remaining valencies of the carbon atom and of the nitrogen atom in formula (1) may be linked to various radicals such as a hydrogen atom, a hydrocarbon-based radical such as an alkyl, aryl or arylalkyl radical, comprising from 1 to 10 carbon atoms. It is not excluded for the carbon atom and the nitrogen atom in formula (1) to be linked together via a divalent radical, so as to form a ring. Preferably, however, the remaining valencies of the carbon atom and of the nitrogen atom of formula (1) are linked to monovalent radicals. Preferably, the radical R_{L} has a molar mass of greater than 30 g/mol. The radical R_{L} may have, for example, a molar mass of between 40 and 450 g/mol. By way of example, the radical R_{L} may be a radical comprising a phosphoryl group, said radical R_{L} possibly being represented by the formula:

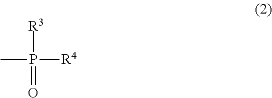

in which R³ and R⁴, which may be identical or different, may be chosen from alkyl, cycloalkyl, alkoxy, aryloxy, aryl, aralkyloxy, perfluoroalkyl and aralkyl radicals, and may comprise from 1 to 20 carbon atoms. R³ and/or R⁴ may also be a halogen atom such as a chlorine or bromine or fluorine or iodine atom. The radical R_{L} may also comprise at least one aromatic ring as for the phenyl radical or the naphthyl radical, the latter possibly being substituted, for example, with an alkyl radical comprising from 1 to 4 carbon atoms.

More particularly, the alkoxyamines derived from the following stable radicals are preferred:
N-tert-butyl-1-phenyl-2-methyl propyl nitroxide,
N-tert-butyl-1-(2-naphthyl)-2-methyl propyl nitroxide,
N-tert-butyl-1-diethylphosphono-2,2-dimethyl propyl nitroxide,
N-tert-butyl-1-dibenzylphosphono-2,2-dimethyl propyl nitroxide,
N-phenyl-1-diethylphosphono-2,2-dimethyl propyl nitroxide,
N-phenyl-1-diethylphosphono-1-methyl ethyl nitroxide,
N-(1-phenyl-2-methylpropyl)-1-diethylphosphono-1-methyl ethyl nitroxide,
4-oxo-2,2,6,6-tetramethyl-1-piperidinyloxy,
2,4,6-tri-tert-butylphenoxy.

The alkoxyamines used in controlled radical polymerization must allow good control of the monomer sequence. Thus, they do not all allow good control of certain monomers. For example, the alkoxyamines derived from TEMPO allow control of only a limited number of monomers, and this is likewise the case for the alkoxyamines derived from 2,2,5-trimethyl-4-phenyl-3-azahexane 3-nitroxide (TIPNO). On the other hand, other alkoxyamines derived from the nitroxides corresponding to formula (1), particularly those derived from the nitroxides corresponding to formula (2) and even more particularly those derived from N-tert-butyl-1-diethylphosphono-2,2-dimethyl propyl nitroxide, make it possible to broaden the controlled radical polymerization of these monomers to a large number of monomers.

In addition, the open temperature of the alkoxyamines also has an influence on the economic factor. The use of low temperatures will be preferred to minimize the industrial difficulties. The alkoxyamines derived from the nitroxides corresponding to formula (1) will thus be preferred, particularly those derived from the nitroxides corresponding to formula (2) and even more particularly those derived from N-tert-butyl-1-diethylphosphono-2,2-dimethyl propyl nitroxide over those derived from TEMPO or 2,2,5-trimethyl-4-phenyl-3-azahexane 3-nitroxide (TIPNO).

The constituent monomers of the random copolymers (being a minimum of two) will be chosen from vinyl, vinylidene, diene, olefin, allylic and (meth)acrylic monomers. These monomers are chosen more particularly from vinylaromatic monomers such as styrene or substituted styrenes, especially alpha-methylstyrene, acrylic monomers such as acrylic acid or salts thereof, alkyl, cycloalkyl or aryl acrylates such as methyl, ethyl, butyl, ethylhexyl or phenyl acrylate, hydroxyalkyl acrylates such as 2-hydroxyethyl acrylate, ether alkyl acrylates such as 2-methoxyethyl acrylate, alkoxy- or aryloxy-polyalkylene glycol acrylates such as methoxypolyethylene glycol acrylates, ethoxypolyethylene glycol acrylates, methoxypolypropylene glycol acrylates, methoxypolyethylene glycol-polypropylene glycol acrylates or mixtures thereof, amino alkyl acrylates such as 2-(dimethylamino)ethyl acrylate (DMAEA), fluoro acrylates, silyl acrylates, phosphorus-based acrylates such as alkylene glycol phosphate acrylates, glycidyl or dicyclopentenyloxyethyl acrylates, methacrylic monomers such as methacrylic acid or salts thereof, alkyl, cycloalkyl, alkenyl or aryl methacrylates such as methyl methacrylate (MMA), lauryl, cyclohexyl, allyl, phenyl or naphthyl methacrylate, hydroxyalkyl methacrylates such as 2-hydroxyethyl methacrylate or 2-hydroxypropyl methacrylate, ether alkyl methacrylates such as 2-ethoxyethyl methacrylate, alkoxy- or aryloxy-polyalkylene glycol methacrylates such as methoxypolyethylene glycol methacrylates, ethoxypolyethylene glycol methacrylates, methoxypolypropylene glycol methacrylates, methoxypolyethylene glycol-polypropylene glycol methacrylates or mixtures thereof, aminoalkyl methacrylates such as 2-(dimethylamino)ethyl methacrylate (DMAEMA), fluoro methacrylates such as 2,2,2-trifluoroethyl methacrylate, silyl methacrylates such as 3-meth-acryloylpropyltrimethylsilane, phosphorus-based methacrylates such as alkylene glycol phosphate methacrylates, hydroxyethylimidazolidone methacrylate, hydroxyethylimidazolidinone methacrylate, 2-(2-oxo-1-imidazolidinyl)ethyl methacrylate, acrylonitrile, acrylamide or substituted acrylamides, 4-acryloylmorpholine, N-methylolacrylamide, methacrylamide or substituted methacrylamides, N-methylolmethacrylamide, methacrylamidopropyltrimethylammonium chloride (MAPTAC), glycidyl or dicyclopentenyloxyethyl methacrylates, itaconic acid, maleic acid or salts thereof, maleic anhydride, alkyl or alkoxy- or aryloxy-polyalkylene glycol maleates or hemimaleates, vinylpyridine, vinylpyrrolidinone, (alkoxy)poly(alkylene glycol) vinyl ether or divinyl ether, such as methoxy poly(ethylene glycol) vinyl ether, poly(ethylene glycol) divinylether, olefin monomers, among which mention may be made of ethylene, butene, hexene and 1-octene, diene monomers including butadiene and isoprene, and also fluoro olefinic monomers, and vinylidene monomers, among which mention may be made of vinylidene fluoride.

Preferably, the constituent monomers of the random copolymers will be chosen from styrene or (meth)acrylic monomers, and more particularly styrene and methyl methacrylate.

As regards the number-average molecular mass of the random copolymers used in the invention, it may be between 500 g/mol and 100 000 g/mol and preferably between 1000 g/mol and 20 000 g/mol, and even more particularly between 2000 g/mol and 10 000 g/mol with a dispersity index from 1.00 to 10 and preferably from 1.05 to 3 and more particularly between 1.05 and 2.

The block copolymers used in the invention may be of any type (diblocks, triblocks, multi-blocks, gradient or starburst copolymers), on condition that the constituent monomers thereof are of different chemical nature from those present in the random copolymers used in the invention.

The block copolymers used in the invention may be prepared via any synthetic route such as anionic polymerization, oligomer polycondensation, ring-opening polymerization or controlled radical polymerization.

The constituent blocks will be chosen from the following blocks:

PLA, PDMS, polytrimethyl carbonate (PTMC), polycaprolactone (PCL).

Preferably, the block copolymers used in the invention will be chosen from the following: PLA-PDMS, PLA-PDMS-PLA, PTMC-PDMS-PTMC, PCL-PDMS-PCL, PTMC-PCL, PTMC-PCL-PTMC, PCL-PTMC-PCL, and more particularly PLA-PDMS-PLA, PTMC-PDMS-PTMC.

Consideration may also be given to block copolymers in which one of the blocks contains styrene and at least one comonomer X, the other block containing methyl methacrylate and at least one comonomer Y, X being chosen from the following species: hydrogenated or partially hydrogenated styrene, cyclohexadiene, cyclohexene, cyclohexane, styrene substituted with one or more fluoro alkyl groups, or mixtures thereof in mass proportions of X ranging from 1% to 99% and preferably from 10% to 80% relative to the block containing styrene; Y being chosen from the following species: fluoro alkyl (meth)acrylate, particularly trifluoroethyl methacrylate, dimethylaminoethyl (meth)acrylate, globular (meth)acrylates such as isobornyl or halogenated isobornyl (meth)acrylates, halogenated alkyl (meth) acrylate, naphthyl (meth) acrylate, polyhedral oligomeric silsesquioxane (meth)acrylate which may contain a fluoro group, or mixtures thereof, in mass proportions of Y ranging from 1% to 99% and preferably from 10% to 80% relative to the block containing methyl methacrylate.

As regards the number-average molecular mass of the block copolymers used in the invention, measured by SEC with polystyrene standards, it may be between 2000 g/mol and 80 000 g/mol and preferably between 4000 g/mol and 20 000 g/mol, and even more particularly between 6000 g/mol and 15 000 g/mol with a dispersity index of 1.00 to 2 and preferably 1.05 and 1.4.

The ratios between the constituent blocks will be chosen in the following manner:

The various mesostructures of the block copolymers depend on the volume fractions of the blocks. Theoretical studies conducted by Masten et al. in “Equilibrium behavior of symmetric ABA triblock copolymers melts. The Journal of chemical physics, 1999”, 111(15): 7139-7146, show that by varying the volume fractions of the blocks, the mesostructures may be spherical, cylindrical, lamellar, gyroid, etc. For example, a mesostructure showing a stack of compact hexagonal type may be obtained with volume fractions of ˜70% for one block and ˜30% for the other block.

Thus, to obtain lines, we will use a linear or nonlinear block copolymer of AB, ABA or ABC type having a lamellar mesostructure. To obtain plots, we may use the same type of block copolymers, but having spherical or cylindrical mesostructures and by degrading the matrix domain. To obtain holes, we may use the same type of block copolymers having spherical or cylindrical mesostructures and by degrading the cylinders or spheres of the minor phase.

Moreover, the block copolymers with high χ values, the Flory-Huggins parameter, will have a high phase separation of the blocks. Specifically, this parameter is relative to the interactions between the chains of each of the blocks. A high χ value means that the blocks distance themselves from each other as much as possible, the consequence of which will be good resolution of the blocks, and thus a low line roughness.

Block copolymer systems with a high Flory-Huggins parameter (i.e. greater than 0.1 at 298 K) will thus be preferred, and more particularly polymer blocks containing heteroatoms (atoms other than C and H), and even more particularly Si atoms.

The treatments suited to the phase segregation inherent in the self-assembly of the block copolymers may be thermal annealing, typically above the glass transition temperatures (Tg) of the blocks, which may range from 10 to 150° C. above the highest Tg, exposure to solvent vapors, or a combination of these two treatments. Preferably, it is a heat treatment in which the temperature will depend on the blocks chosen. Where appropriate, for example when the blocks are carefully chosen, simple evaporation of the solvent will suffice, at room temperature, to promote the self-assembly of the block copolymer.

The process of the invention may be applied to the following substrates: silicon, silicon with a layer of native or thermal oxide, hydrogenated or halogenated silicon, germanium, hydrogenated or halogenated germanium, platinum and platinum oxides, tungsten and tungsten oxides, gold, titanium nitrides, graphenes. Preferably, the surface is mineral and more preferentially silicon. Even more preferentially, the surface is silicon with a layer of native or thermal oxide.

The process of the invention used for controlling the orientation of a mesostructure of block copolymer by means of a random copolymer consists in preferably depositing the random copolymers predissolved or predispersed in a suitable solvent according to techniques known to those skilled in the art, for instance the “spincoating”, “doctor blade”, “knife system” or “slot die system” technique, but any other technique may be used, such as dry deposition, i.e. without proceeding via predissolution.

The process of the invention will be directed toward forming a layer of random copolymer typically less than 10 nm and preferably less than 5 nm.

The block copolymer used in the process of the invention will then be deposited via a similar technique, and then subjected to the treatment allowing the phase segregation inherent to the self-assembly of block copolymers.

According to a preferred form of the invention, the block copolymers deposited on the surfaces treated via the process of the invention are preferably linear or starburst diblock copolymers or triblock copolymers.

The surfaces treated via the process of the invention will be used in lithography and membrane preparation applications.

### EXAMPLES

### Example 1

### Preparation of a Hydroxy-Functionalized Alkoxyamine Starting with the Commercial Alkoxyamine BlocBuilder®MA

The following are introduced into a 1 L round-bottomed flask purged with nitrogen:
226.17 g of BlocBuilder®MA (1 equivalent)
68.9 g of 2-hydroxyethyl acrylate (1 equivalent)
548 g of isopropanol.

The reaction mixture is refluxed (80° C.) for 4 hours and the isopropanol is then evaporated off under vacuum. 297 g of hydroxy-functionalized alkoxyamine are obtained in the form of a very viscous yellow oil.

### Example 2

Experimental protocol for preparing polystyrene/polymethyl methacrylate polymers, starting with the hydroxy-functionalized alkoxyamine prepared according to Example 1.

Toluene and monomers such as styrene (S), methyl methacrylate (MMA) and the hydroxy-functionalized alkoxyamine are placed in a stainless-steel reactor equipped with a mechanical stirrer and a jacket. The mass ratios between the various monomers styrene (S) and methyl methacrylate (MMA) are described in table 1. The mass amount of toluene fed in is set at 30% relative to the reaction medium. The reaction mixture is stirred and degassed by sparging with nitrogen at room temperature for 30 minutes.

The temperature of the reaction medium is then brought to 115° C. Time t=0 is started at room temperature. The temperature is maintained at 115° C. throughout the polymerization until a monomer conversion of about 70% is achieved. Samples are taken at regular intervals in order to determine the polymerization kinetics by gravimetry (measurement on dry extract).

When a conversion rate of 70% is reached, the reaction medium is cooled to 60° C. and the solvent and residual monomers are evaporated off under vacuum. After evaporation, methyl ethyl ketone is added to the reaction medium in an amount such that a polymer solution of about 25% by mass is produced.

This polymer solution is then introduced dropwise into a beaker containing a non-solvent (heptane), so as to precipitate the polymer. The mass ratio between solvent and non-solvent (methyl ethyl ketone/heptane) is about 1/10. The precipitated polymer is recovered in the form of a white powder after filtration and drying.

TABLE 1

| | Initial reaction state | | | | | | | |
|---|---|---|---|---|---|---|---|---|
| | | | Mass | | | | | |
| | Initial | | ratio of | | | | | |
| | mass | | initiator | | | | | |
| | composition | Nature of | relative | | | | | |
| | of the | the | to the | | | | | |
| | monomers | initiator | monomers | Characteristics of the copolymer | | | | |
| Copolymers | S/MMA | used | S, MMA | % PS^{(a)} | Mp^{(a)} | Mn^{(a)} | Mw^{(a)} | Ip^{(a)} |
| 1 | 58/42 | Alkoxyamine | 0.03 | 64% | 16 440 | 11 870 | 16 670 | 1.4 |
| | | of | | | | | | |
| | | Example 1 | | | | | | |
| 2 | 58/42 | Alkoxyamine | 0.02 | 60% | 49 020 | 23 150 | 46 280 | 2.0 |
| | | of | | | | | | |
| | | Example 1 | | | | | | |

^{(a)}Determined by steric exclusion chromatography.

The polymers are dissolved at 1 g/l in THF stabilized with BHT. The calibration is performed by means of monodisperse polystyrene standards. Double detection by refractive index and UV at 254 nm makes it possible to determine the percentage of polystyrene in the polymer.

### Example 3

### Synthesis of the PLA-PDMS-PLA Triblock Copolymer

The products used for this synthesis are an HO-PDMS-OH initiator and homopolymer sold by Sigma-Aldrich, a racemic lactic acid, so as to avoid any crystallization-related problem, an organic catalyst to avoid the problems of metal contamination, triazabicyclodecene (TBD) and toluene.

The volume fractions of the blocks were determined to obtain PLA cylinders in a PDMS matrix, i.e. about 70% PDMS and 30% PLA.

### Example 4

### Self-Assembly of a PLA-b-PDMS-b-PLA Triblock Copolymer

The block copolymer described in this study was chosen as a function of the lithography needs, i.e. cylinders in a matrix, used as masks for creating cylindrical holes in a substrate after etching and degradation. The desired morphology is thus PLA cylinders in a PDMS matrix.

First Step: Grafting of a Layer of Random Copolymer.

A random copolymer brush prepared according to Example 2 is first deposited on the substrate so as to modify the surface energy, and thus the preferential interactions between the blocks and the interfaces.

To do this, the random copolymer is dissolved in a suitable solvent, PGMEA (propylene glycol monomethyl ether acetate). The concentration of the solution may range from 0.5 to 5% and more precisely from 1% to 3%. The chain attachment density is limited by the length of the chains of the random copolymer, by its molecular mass and by its turning radius; thus, having a concentration stronger than 5% is unnecessary. After total dissolution of the random copolymer, the solution is filtered through 0.2 μm filters.

The substrate is cut up and cleaned with the same solvent, PGMEA, and then dried with compressed air. Next, the substrate is deposited on the spinner, and 100 μL of solution are deposited on the substrate. The spinner is finally switched on. Once the deposition is complete, and the solvent has evaporated off, the film is placed in an oven under vacuum for 48 hours at 170° C. in order for the grafting to take place.

After 48 hours of annealing, and once the oven has returned to room temperature, the film is rinsed with PGMEA so as to remove the excess random copolymer not grafted to the substrate, and then dried with compressed air.

2^{nd} Step: Self-Assembly of the Block Copolymer

The block copolymer in Example 3 is dissolved in PGMEA. The concentration of the solution is between 0.5% and 10% and more precisely between 1% and 4%. The film thickness depends on the concentration of the solution: the higher the concentration, the thicker the film. Thus, the concentration is the parameter to be varied depending on the desired film thickness. After total dissolution of the block copolymer, the solution is filtered through 0.2 μm filters.

The grafted substrate is deposited on the spinner, and 100 μL of solution containing the block copolymer of Example are then deposited on the substrate. The spinner is started. Thermal annealing for 90 minutes at 180° C. is then used so as to aid the self-organization of the mesostructure.

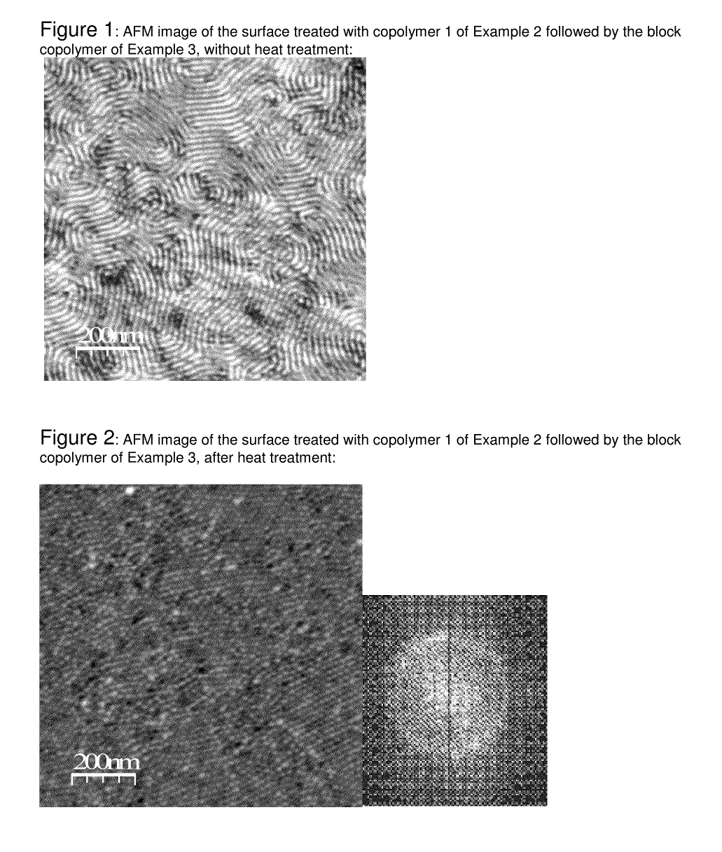

The effect of the copolymer 1 of Example 2 on the self-organization of the block copolymer of Example 3 may be seen in FIGS. 1 and 2.

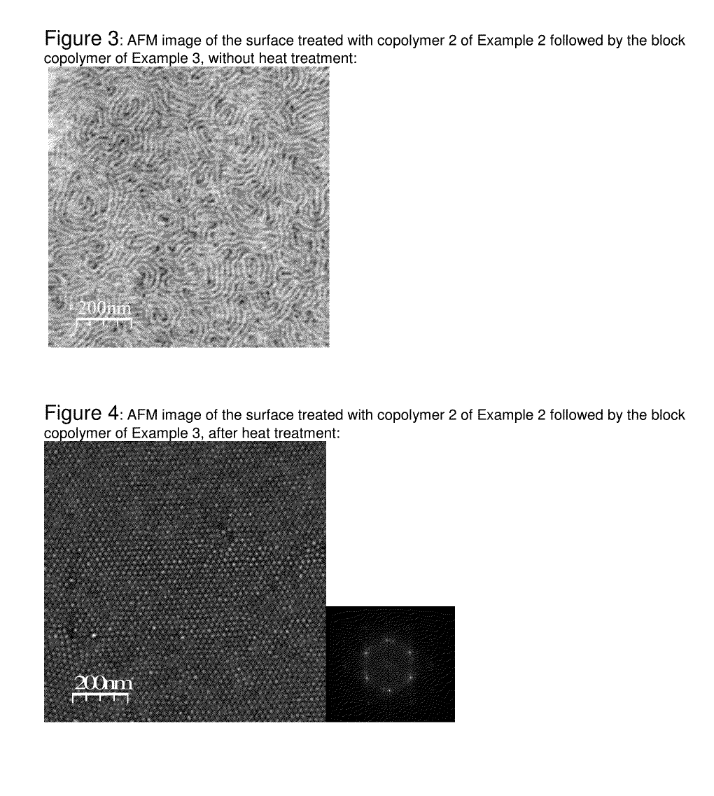

The effect of the copolymer 2 of Example 2 on the self-organization of the block copolymer of Example 3 may be seen in FIGS. 3 and 4.

1. A process for controlling the orientation of a block copolymer mesostructure by means of a random or gradient copolymer whose monomers differ at least in part from those present, respectively, in each of the blocks of the block copolymer, comprising the following steps:
depositing a solution of the random or gradient copolymer on a substrate;
annealing bringing about the grafting of a monolayer of the chains of the random or gradient copolymer on the substrate, followed by optional rinsing so as to remove ungrafted chains;
depositing a solution of the block copolymer;
phase segregation inherent in the self-assembly of the block copolymers via a suitable treatment.

2. The process as claimed in claim 1, wherein one of the constituent monomers of the random or gradient copolymer is miscible once polymerized in one of the blocks of the block copolymer.

3. The process as claimed in claim 1, wherein the random or gradient copolymer is prepared by radical polymerization.

4. The process as claimed in claim 1, wherein the random or gradient copolymer is prepared by controlled radical polymerization.

5. The process as claimed in claim 1, wherein the random or gradient copolymer is prepared by nitroxide-mediated radical polymerization.

6. The process as claimed in claim 5, wherein the nitroxide is N-tert-butyl-1-diethylphosphono-2,2-dimethylpropyl nitroxide.

7. The process as claimed in claim 1, wherein the block copolymer comprises at least one PLA block and at least one PDMS block.

8. The process as claimed in claim 1, wherein the block copolymer comprises at least one PTMC block and at least one PDMS block.

9. The process as claimed in claim 6, wherein the random or gradient copolymer comprises methyl methacrylate and styrene.

10. The process as claimed in claim 1, wherein the process is used in a lithography application.

11. The process as claimed in claim 1, wherein the suitable treatment is selected from thermal annealing, exposing the block copolymers to solvent vapors, or a combination thereof.

12. The process as claimed in claim 1, wherein the suitable treatment is evaporating the solvent at room temperature.

13. The process as claimed in claim 1, wherein annealing results in forming a layer of random or gradient copolymer on the substrate having a thickness less than 10 nm.
